(19) United States
(12) Patent Application Publication
(10) Pub. No.: US 2012/0286846 A1
(43) Pub. Date: Nov. 15, 2012

(54) SWITCHING CIRCUIT

(76) Inventors: Olaf Wunnicke, Eindhoven (NL); Willem Frederik Adrianus Besling, Eindhoven (NL); Gerrit Willem den Besten, Eindhoven (NL); Michael Joehren, Pinneberg (DE); Klaus Reimann, Eindhoven (NL); James Raymond Spehar, Chandler, AZ (US); Peter Gerard Steeneken, Valkenswaard (NL)

(21) Appl. No.: 13/105,591

(22) Filed: May 11, 2011

(51) Int. Cl. H03K 17/00

(52) U.S. Cl. 327/403

(57) ABSTRACT

A switching circuit employs switches operating at low on resistance and high off capacitance. In connection with various example embodiments, a switching circuit selectively couples a communication port to one of two or more internal circuits based upon a type of input at the communication port. A sensor circuit senses the type of the input and, based upon the sensed input type, actuates one or more switches in the switching circuit.

Various aspects of the present invention are directed to switches, and more particularly to switching circuits including mechanically-actuated switches.

Electronic devices, and in particular mobile electronic devices, have grown dramatically in functionality and needs with respect to power and data connectivity, while the demand for such devices and high data rates and bandwidth therewith continues to rise. In particular, the data rate of standards for the transmission of digital signals has been continually increasing. For instance, recent versions of the PCI Express bus (e.g., 3.0) require a transmission rate of 8 Gb/s. The USB 3.0 standard supports 5 Gb/s. Such standards are pushing towards (and beyond) 10 Gb/s, and are expected to continue to increase.

While the demands upon communication speed have been increasing, circuits used to terminate and switch communication lines have experienced difficulties in meeting bandwidth, loss and other characteristics pertaining to these communications. Most broad frequency bandwidth switches, such as transistor-based switches, behave as a resistor when closed, and as a capacitor when open. Low resistance and capacitance can be desirable, but can be limited due to the voltage levels of signals that are passed via the transistor-based switches. It has been challenging to reduce both closed/on resistance and open/off capacitance while achieving desirable voltage signal values. For example, increasing the area of a transistor can reduce its resistance, but increase its capacitance such that the product of resistance and capacitance remains roughly constant. Other approaches to reducing this resistance-capacitance product can adversely affect achievable signal voltage. Further, many approaches are susceptible to non-linear behavior.

In addition, many mobile devices require separate connectors for high data rate signals (e.g., for communications), and for high-current signals (e.g., for power). Certain devices combine both high data rate and high-current connectors in one, often employ rather large connectors to suit this need. Space requirements and design constraints associated with such larger connectors can be undesirable. Other approaches, such as those involving the separation of data and power types of signals using LCR filtering can be subject to undesirable resonances and distortion.

Accordingly, providing connectivity for devices in a variety of applications, and particularly for high-bandwidth and power applications, continues to be challenging.

Various example embodiments are directed to MEMS switching circuits for a variety of applications and addressing various challenges, including those discussed above.

In connection with an example embodiment, a switching circuit for an electronic device includes a communication port, a plurality of MEMS switch circuits and a sensing control circuit. Each of the plurality of MEMS switch circuits is respectively configured to electrically couple the communication port to one or more of different circuits in the electronic device. At least one MEMS switch circuit couples power between the communication port and an internal circuit in the electronic device, and at least one MEMS switch circuit couples data between the communication port and an internal circuit in the electronic device. In various embodiments, one of the MEMS switch circuits couples both power and data between the communication port and an internal circuit. The sensing control circuit configured to sense a type of connection at the communication port and, based upon the sensed type of connection, actuate at least one of the MEMS switch circuits between an open position in which the communication port is not electrically coupled via the at least one of the MEMS switch circuits, and a closed position in which the communication port is electrically coupled via the at least one of the MEMS switch circuits to at least one of the internal circuits.

Another example embodiment is directed to a method for switching a connection between a communication port and a plurality of different circuits in an electronic device, in which the different circuits include circuits using power and/or data. A type of connection is sensed at the communication port and, based upon the sensed type of connection, at least one of a plurality of MEMS switch circuits is actuated between an open position in which the communication port is not electrically coupled via the at least one of the MEMS switch circuits, and a closed position in which the communication port is electrically coupled via the at least one of the MEMS switch circuits to at least one of the power and data circuits.

Another example embodiment is directed to a switching circuit for an electronic device, the switching circuit including a communication port and a dynamic switch circuit. The dynamic switch circuit includes a plurality of switches respectively configured to selectively electrically couple the communication port to different circuits in the electronic device responsive to a type of connection detected at the communication port. Each of the switches operates at an on resistance Rₒₙ and off capacitance C_{off} having a product Rₒₙ* C_{off}<300 fs. At least one of the switches is configured to couple power between the communication port and an internal circuit in the electronic device, and at least one of the switches is configured to couple data between the communication port and an internal circuit in the electronic device.

The above discussion is not intended to describe each embodiment or every implementation of the present disclosure. The figures and following description also exemplify various embodiments.

Various example embodiments may be more completely understood in consideration of the following detailed description in connection with the accompanying drawings, in which:

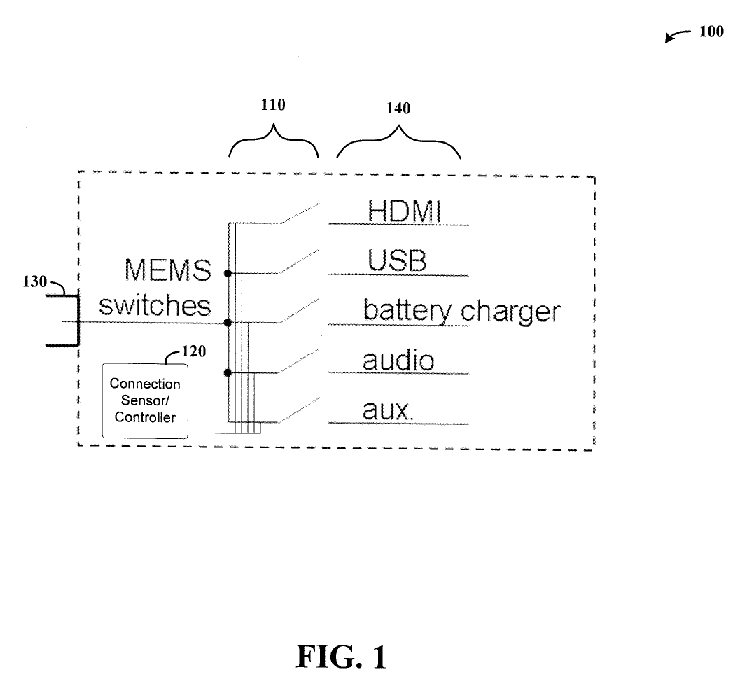

FIG. 1 shows a MEMS switching arrangement, in accordance with an example embodiment of the present invention;

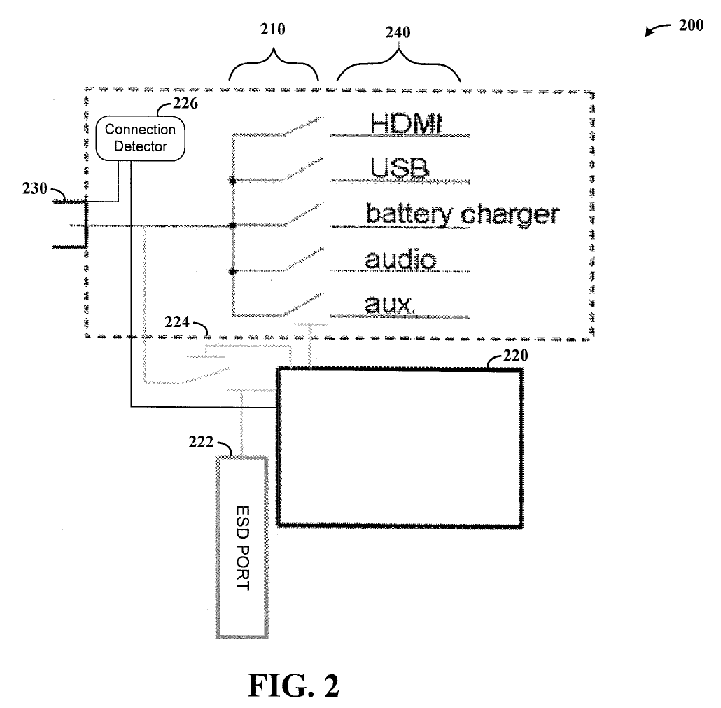

FIG. 2 shows a MEMS-based switching arrangement with a coupled signal detector, in accordance with another example embodiment of the present invention;

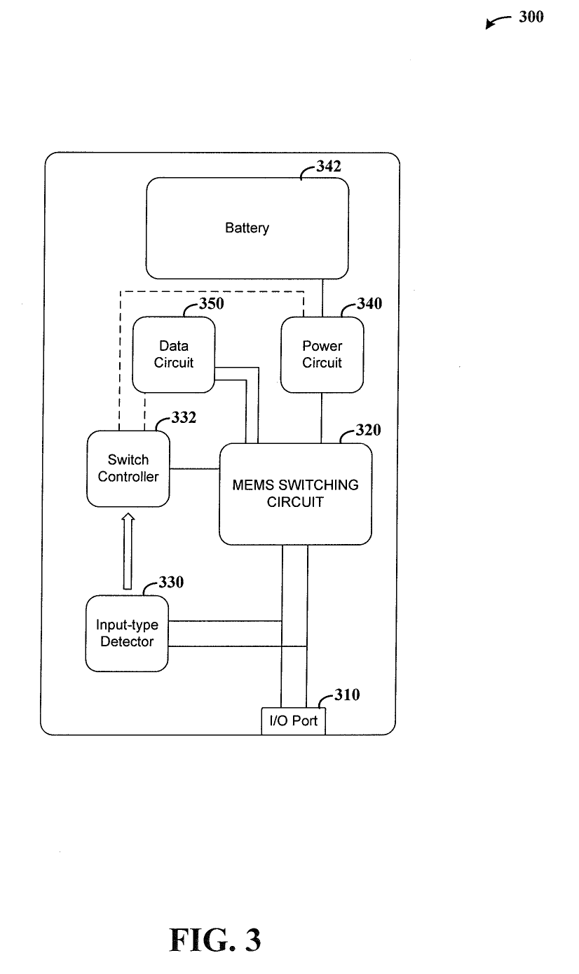

FIG. 3 shows a portable electronic device with a MEMS-based switching arrangement, power and data circuits, in accordance with another example embodiment of the present invention; and

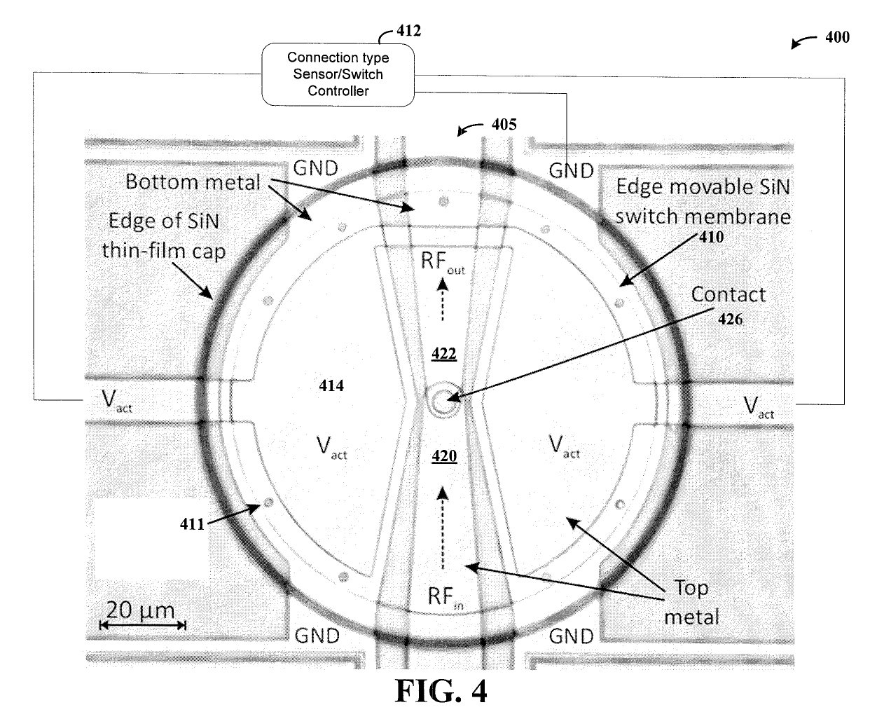

FIG. 4 shows a top view of a MEMS switching arrangement with a connector-type sensor, in accordance with another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention including aspects defined in the claims. Furthermore, the term “example” as used throughout this document is by way of illustration, and not limitation.

The present invention is believed to be applicable to a variety of different types of circuits, devices and arrangements involving switches or switching components, including MEMS-based switching circuits that switch different types of signals on a common communications line. While the present invention is not necessarily limited in this context, various aspects of the invention may be appreciated through a discussion of related examples.

In accordance with various example embodiments, a microelectromechanical systems (MEMS)-based switching circuit includes a plurality of MEMS switches that operate to couple different types of signals passed through a common interface. The switching circuit passes high-speed signals, such as those associated with high radio frequency (RF) signals and high-speed serial data streams, to data circuits appropriate for the signals. The switching circuit also passes low frequency (LF), high current signals in the same signal path. In many embodiments, such as for audio communications (e.g., a speaker), or data communications having power associated therewith, power and data are passed via the same switch.

In various implementations, the MEMS switches are configured to operate with an RC value, corresponding to the product of resistance and capacitance values respectively in the on and off states, that is several orders of magnitude lower that such products with various transistor-based circuits. Accordingly, ohmic-type MEMS switches can be implemented using this approach, to achieve low on resistances and low off capacitances. This approach facilitates the use of a relatively large contact area in the MEMS switches to handle relatively large current while maintaining desirable RF (high frequency) characteristics. For general information regarding membranes and MEMS switches, and for specific information regarding MEMS switches that may be implemented in connection with one or more example embodiments herein, reference may be made to Wunnicke et al., “Small, low-ohmic RF MEMS switches with thin-film package,” Proc. IEEE MEMS 2011, Jan. 23-27 2011, page 793 (2011), which is fully incorporated herein by reference.

In accordance with another example embodiment, a switching circuit includes MEMS switches for coupling different types of connectors to circuitry in an electronic device. A communication port (e.g., an input/output port) communicates (receives and/or sends) different types of inputs and outputs, including power and data and combinations of power and data. Both AC and DC may be passed using these approaches, to pass (communicate) power between the communication port and an internal circuit. In addition, the switch may pass information in a bidirectional manner, such as for data communications.

For each of the different types of inputs/outputs to be served by the switching circuit, a MEMS switch couples the communication port to a circuit in the mobile device. Accordingly, at least one MEMS switch couples power to a power circuit in the mobile device, and at least another MEMS switch couples data to a data circuit in the mobile device. A sensing control circuit senses a type of connection made to the communication port and then, based upon the sensed type of connection, actuates at least one of the MEMS switches to move between open and closed positions for coupling the communication port with at least one of the power and data circuits in the device.

In some implementations, each MEMS switch includes a substrate having a substrate contact electrode and a bias circuit, and a suspended membrane including a membrane contact electrode and another bias circuit. The membrane being moves between an open position and a closed position for respectively engaging and disengaging the contact electrodes to pass and block signals between the communication port and the circuit in the mobile device to which the MEMS switch is connected.

In some embodiments, the MEMS switches are actuated via a voltage bias applied by a controller to selectively control the state (open/closed) of each MEMS switch. This voltage bias can be applied, for example, to effect an electrostatic or piezoelectric bias to move a membrane having an electrode (or electrodes) therein, to bring the electrode in contact with another electrode and/or to move break contact of the electrodes.

The MEMS-based switches are implemented using one or more of a variety of components, generally involving an ohmic or metal-contact material to achieve wide bandwidth. In various contexts, the switches are configured to achieve a resistance in the on/closed state that is less than 3 Ohms, and an insertion loss of less than about 2 dB. In the off/open state, the switches are configured to achieve an isolation between electrodes of at least 25 dB. These characteristics can be achieved for signals in a frequency range from 0 Hz to above 10 GHz. This approach may be implemented to facilitate connection to cables carrying high data rate digital signals, such as for PCI Express, DisplayPort, HDMI, eSATA, or USB 3.0. Such a data rate may include, for example, a rate higher than 2 Gb/s, higher than 5 Gb/s, or higher than 10 Gb/s. In some implementations, each channel is designed to operate as a 50 Ohm transmission line between the frequencies 100 kHz and 10 GHz when a corresponding MEMS switch is closed. In accordance with these implementations, it has been discovered that the implementation of MEMS-based switches with membranes as discussed herein (e.g., at exhibited distances of separation), can be used to achieve such data rates, signal loss and other transmission characteristics as described above.

A variety of different types of inputs can be switched using MEMS-based switching circuits as discussed herein. For example, both single-ended and differential signals can be passed, with single-ended signals carrying a signal voltage on one line and holds the other line at ground, and with differential signals using pairs of switches to pass signals of opposite polarity. The switches may pass digital binary signals composed of arbitrary sequences of two voltage levels (e.g., 3V=1 and 0 V=0), direct current (DC) signals, radio frequency (RF) signals, and bi-directional signals as well. Analog input/output signals, RF signals, digital signals and modulated digital signals can all be passed using these approaches. In connection with various embodiments, MEMS-based switches having a resistance that depends very little on the amplitude or sign of the signal voltage are used to achieve desirable linearity, maintain the shape of the electrical waveform, permit negative voltages to pass through the switch and simplify differential signal circuit designs.

In some implementations, a shared electrical conductor connects a communication port and a plurality of MEMS switch circuits as discussed herein. The MEMS switch circuits respectively couple the communication port to different circuits in the electronic device using the shared electrical conductor to provide connections between the communication port and MEMS switch circuits for electrically coupling both power and data between the communication port and the MEMS switch circuit.

Turning now to the Figures, FIG. 1 shows a MEMS switching arrangement 100, in accordance with another example embodiment of the present invention. The switching arrangement 100 facilitates the provision of universal-type connector functions that can be used for a plurality (two or more) of different types of connections, such as high RF, high data rate connections (e.g., HDMI, USB), and low frequency (LF), high current connections (e.g., audio signals, power for charging a battery), and multipurpose antenna connections for receiving different types of signals (data and power). In addition, the connector functions can provide connectivity for different types of connectors having different numbers of signal channels.

The switching arrangement 100 includes MEMS switches 110, with five switches shown and controlled by a connection-type sensor/controller 120 that senses a type of connection made at a communication port 130 (e.g., an I/O port). The type of connection may be sensed, for example, by detecting a type of data passed via the communication port 130, detecting a frequency (e.g., with low frequency signals corresponding to power, and higher frequency signals corresponding to data), detecting a voltage level, detecting signals characteristic of an input type, detecting a power source (e.g., based on an amount of current that can be drawn from the source to which I/O port is connected), using information in a data stream identifying a type of source, or in other manners. A dedicated line in the communication port 130 can also be used to communicate a signal type, or a shape of a connector and/or a mechanical switch coupled at the communication port can be used to detect a signal type.

By way of example, the five switches are shown for coupling the communication port 130 to HDMI, USB, battery charger (power), audio and auxiliary (aux.) circuits 140. All signals (as also applicable to power connections) see the sum of the off-capacitance of all switches. The sensor/controller 120 applies a voltage to an appropriate switch or combination of switches to make a connection between the communication port 130 and one of the circuits 140. Further, while one switch is represented for each of the circuits 140 in FIG. 1, one or more of the switches as represented may be implemented with two (or more) switches, such as for connecting to a connector employing two or more channels. In addition, the switches can be implemented to pass communications from different types of connectors having different numbers of channels

In some embodiments, MEMS switches 110 are configured to switch audio signals while injecting little or no charge into the audio signal path. The switches 110 are thus configured to mitigate or eliminate capacitance charging or discharging, which can cause audible clicks. Accordingly, audible clicks are mitigated or otherwise not generated during the actuation of the switch (e.g., while changing the input source of an audio amplifier).

The sensor/controller 120 can be implemented using one or more of a variety of different types of sensors, to suit various embodiments. In one embodiment, sensor/controller 120 includes a MEMS switch that connects the sensor/controller to the communication port 130 for detecting an input type thereat, and disconnects the sensor/controller from the communication port thereafter. This approach can be used, for example, to ensure that the sensor/controller 120 does not add capacitance to the communication port after a proper connection is made via the MEMS switches 110.

In a particular embodiment, the communication port 130 is connected to a multipurpose antenna that receives different types of signals including signals providing at least one of data and power. The sensor/controller 120 detects a type of signal received via the multipurpose antenna and controls the MEMS switches 110 to electrically couple the multipurpose antenna to different internal circuits based upon the detected type of signal received via the multipurpose antenna.

FIG. 2 shows a MEMS-based switching arrangement 200 with a coupled signal detector, in accordance with another example embodiment of the present invention. The switching arrangement 200 includes MEMS switches 210, with five switches shown and controlled by a connection-type sensor/controller 220 that senses a type of connection made at communication port 230.

By way of example (and similar to FIG. 1), the five switches are shown for coupling the communication port 230 to HDMI, USB, battery charger (power), audio and auxiliary (aux.) circuits 240. The sensor/controller 220 applies a voltage to an appropriate switch or combination of switches to make a connection between the communication port 230 and one of the circuits 240. Further, while one switch is represented for each of the circuits 240 in FIG. 1, one or more of the switches as represented may be implemented with two (or more) switches, such as for connecting to a connector employing two or more channels.

Other embodiments involve the use of additional MEMS switches, which can be used to connect switches, and to form a multiplexed connection with the communication port 230. For example, a M to N multiplexer can be implemented using M parallel (1 to N) multiplexers. Multiplexers can also be cascaded to provide a few low capacitance inputs, and communication standards with lower data rates (e.g., USB 1, RS 232) can be multiplexed with conventional transistors (or also MEMS switches) after the first MEMS switch.

The switching arrangement 200 also includes a MEMS connector switch 224 that is configured to selectively connect the sensor/controller 220 with the communication port 230 for detecting a type of input thereat. Once an input type is detected, the MEMS connector switch 224 disconnects the sensor/controller 220 from the communication port 230.

In some embodiments, the switching arrangement 200 includes an electrostatic discharge (ESD) protection circuit 222, which shunts ESD pulses to ground to protect the sensor/controller 220 or the MEMS switches 210. In certain implementations, the switching arrangement 200 is configured to maintain the MEMS switches 210 in an open position to electrically isolate the MEMS switches 210 from the communication port 230 until a signal is present, thus decoupling ESD pulses, such as may occur during connection/disconnection of the communication port 230, from the circuits 240.

In certain embodiments, the switching arrangement 200 also includes a connection detector circuit 226 that detects a connection condition of the communication port 230, such as by detecting the connection or disconnection of a cable to the communication port. The detection may, for example, involve a physical detection (e.g., depression or release of a switch via the connection of a cable), an electrical detection at the communication port, or both. The connection detector circuit 226 provides an output to the sensor/controller 220, which operates the connector switch 224 based upon the received output. For example, the connector switch 224 can be closed upon the detection of a connector being coupled to the communication port 230, or in response to detecting the disconnection of a connector from the communication port 230 (such that the sensor/controller 220 is coupled and ready for detecting a new connection to the communication port).

In some implementations, one or both of the sensor/controller 220 and the connection detector 226 operate to monitor the communication port 230 to detect the connection of an external connector thereto. In response to detecting the connection of an external connector to the communication port 230, the connector switch 224 is closed to electrically couple the sensor/controller 220 to the communication port to detect an input type at the communication port. After the input type has been detected, the connector switch 224 is opened to electrically decouple the sensor/controller 220 from the communication port 230 (e.g., by opening a MEMS switch to electrically insulate/isolate internal circuits from the communication port).

In various embodiments, the MEMS switches as shown in FIGS. 1 and/or 2 are replaced with another switch exhibiting low on resistance Rₒₙ and off capacitance C_{off} (RC) product. In one implementation, each of the switches operates at an on resistance Rₒₙ and off capacitance C_{off} having a product Rₒₙ* C_{off}<300 fs. At least one of the switches is configured to couple power between the communication port and an internal circuit in the electronic device, and at least one of the switches is configured to couple data between the communication port and an internal circuit in the electronic device.

FIG. 3 shows a portable electronic device 300, in accordance with another example embodiment of the present invention. The device 300 includes an I/O port 310 having a MEMS-based switching arrangement 320 and an input-type detector 330 connected thereto. The input-type detector 330 detects a type of input at the I/O port 310, and provides an output indicative of the input type to switch controller 332.

In some implementations, the type of the input connector is detected by successively connecting controllers (e.g., as attached to 140, 240, 350 in FIGS. 1-3) to the communication or I/O port to try to negotiate a connection. The sequence of the connection detection can be tailored to suit particular applications, such as those that may involve the connection of a power source (e.g., to ensure an undesirable connection is not inadvertently made). In one implementation, a voltage/power type of connection is made with a communication or I/O port (e.g., 130, 230), and if no power source is detected, one of a plurality of other communication/connection types can be successively coupled to negotiate a connection and therein detect an input type.

Based on the indicated input type, the switch controller 332 applies a voltage to actuate one or more MEMS switches in the MEMS switching circuit 320, to electrically couple the I/O port 310 with an internal circuit appropriate for the detected signal type. For example, when the detected input type is a power input, an appropriate MEMS switch is actuated to couple the I/O port 310 to a power circuit 340, such as for charging a battery 342. In certain implementations, the power circuit 340 is omitted and the MEMS switching circuit 320 is coupled directly to the battery 342 (e.g., to terminals to which a battery is connected, such as in a mobile electronic device). When the detected input type is a data input, an appropriate MEMS switch is actuated to couple the I/O port 310 to a data circuit 350 (e.g., to a video circuit for receiving and/or sending video data via an HDMI type of communication link).

In other embodiments, the switch controller (332) is connected to the internal circuits (340, 350) via another communication link (shown dashed), for detecting or otherwise responding to characteristics at these internal circuits for controlling the MEMS switching circuit 320. For example, in response to detecting that the battery 342 has been fully charged, via the power circuit 340, the switch controller 332 can actuate one or more MEMS switches in the MEMS switching circuit 320 for disconnecting the power circuit 340 from power supplied via the I/O port 310.

FIG. 4 shows a top view of a MEMS switching arrangement 400 with a connector-type sensor, in accordance with another example embodiment of the present invention. The switching arrangement 400 may, for example, be implemented with the switching circuit of FIG. 1. The arrangement 400 includes a MEMS switch 405 having a membrane 410, such as a 700 nm SiN layer (e.g., formed via PECVD. Electrodes 420 and 422 (e.g., 450 nm thick gold electrodes) are selectively coupled to one another via actuation of the membrane 410. A copper electrode below the electrodes is processed (e.g., planarized at 3 μm thick via chemical-mechanical polishing) to reduce the resistance of the interconnect and the switch. The membrane 410 has sacrificial layer etch holes of a diameter of about 2 μm distributed along the edge of the membrane, with hole 411 labeled by way of example.

The switching arrangement 400 also includes a controller 412, which may be implemented in a manner similar to that of controllers 120 and 220 in FIGS. 1 and 2, for controlling two or more MEMS switches as shown with the MEMS switch 405, for coupling an input to different types of circuits. The controller 412 is coupled to supply an actuation voltage across top metal electrode 414, to cause the membrane 410 to deflect towards the underlying electrode and make contact at a central contact 426 for connecting electrodes 420 and 422.

The size of the switch 405 can be set to suit particular applications and communication needs. For example, the membrane 410 can be implemented at a diameter of between about 25 μm and 90 μm, or larger or smaller to suit applications. The switch 405 can be implemented on a variety of different types of substrates, and using a variety of different types of materials. For example, silicon, glass, ceramic, alumina, sapphire, GaAs, GaN, SiC, ceramics such as LTCC and HTCC, and other substrates can be used alone or in combination to suit particular applications. Various embodiments directed to semiconductors substrates may be implemented with one or more components in the substrate. In various implementations, the switch 405 is located on an area of a semiconductor substrate that is at least 100 μm² and less than 10000 μm². The membrane 410 is also arranged relative to the substrate to suit applications, and in some implementations, is arranged such that a gap size between the electrodes 420 and 422 is about 300 nm. In other implementations, the membrane 410 is arranged to position the contact 426 and underlying contact for the electrodes 420 and 422 at a distance of at least 100 nm and less than 200 nm, to achieve desirable on/off circuit characteristics in connection with a limited switch size.

Based upon the above discussion and illustrations, those skilled in the art will readily recognize that various modifications and changes may be made to the present invention without strictly following the exemplary embodiments and applications illustrated and described herein. For example, a variety of different combinations of MEMS-based switches can be made, to suit various connectivity needs for particular applications. In addition, the MEMS-based switches as shown and/or described may be implemented with different types of switches, such as with a GaN switch, a pHEMT (pseudomorphic high electron mobility transistor) switch, or another switch that operates at an on resistance Rₒₙ and off capacitance C_{off} having a product Rₒₙ* C_{off}<300 fs. Such modifications do not depart from the true spirit and scope of the present invention, including that set forth in the following claims.

What is claimed is:

1. A switching circuit for an electronic device, the switching circuit comprising:
a communication port;
a plurality of MEMS switch circuits respectively configured to electrically couple the communication port to different circuits in the electronic device, the plurality of MEMS switch circuits including at least one MEMS switch circuit configured to couple power between the communication port and an internal circuit in the electronic device, and at least one MEMS switch circuit configured to couple data between the communication port and an internal circuit in the electronic device; and
a sensing control circuit configured to sense a type of connection at the communication port and, based upon the sensed type of connection, actuate at least one of the MEMS switch circuits between an open position in which the communication port is not electrically coupled via the at least one of the MEMS switch circuits, and a closed position in which the communication port is electrically coupled via the at least one of the MEMS switch circuits to at least one of the internal circuits.

2. The circuit of claim 1, wherein the plurality of MEMS switch circuits include at least one MEMS switch circuit configured to couple signals from a connector at the communications port having a number of channels that is different than a number of channels coupled by another one of the MEMS switch circuits.

3. The circuit of claim 1, wherein the sensing control circuit is configured to sense a type of connection on the communication port by sensing a frequency of an input signal, and to actuate at least one of the MEMS switch circuits to
provide a low frequency (LF) connection between the communication port and an internal power circuit, and
provide a high frequency connection of a higher frequency than the LF connection between the communication port and an internal data circuit.

4. The circuit of claim 1, wherein
each MEMS switch includes
a substrate having a substrate contact electrode and a bias circuit, and
a suspended membrane including a membrane contact electrode and another bias circuit, the membrane being configured to move between an open position and a closed position for respectively engaging and disengaging the contact electrodes to pass and block signals between the communication port and a circuit in the electronic device to which the MEMS switch is connected; and
the sensing control circuit is configured to actuate the at least one of the MEMS switch circuits by applying a voltage to the biasing circuits of at least one of the MEMS switch circuits and thereby causing the membrane of the one of the MEMS switch circuits to move between the open position in which the contact electrodes are electrically isolated and the closed position in which the contact electrodes are electrically coupled for coupling the communication port with at least one of the internal circuits in the device.

5. The circuit of claim 1, further including a MEMS connector circuit configured and arranged to electrically couple and decouple the sensing control circuit to the communication port for detecting a connection type at the communication port.

6. The circuit of claim 1, further including a MEMS connector circuit configured and arranged to
electrically couple the sensing control circuit to the communication port to detect a connection type at the communication port, and
after the connection type has been detected, electrically decouple the sensing control circuit from the communication port.

7. The circuit of claim 1, further including a MEMS connector circuit configured and arranged to
electrically couple the sensing control circuit to the communication port to detect a connection type at the communication port, in response to the communication port being connected to an external connector, and
after the connection type has been detected, electrically decouple the sensing control circuit from the communication port.

8. The circuit of claim 1, further including a MEMS connector circuit configured and arranged to
in response to the disconnection of an external connector from the communication port, electrically couple the sensing control circuit to the communication port to detect a connection type at the communication port, and
after the input type has been detected, electrically decouple the sensing control circuit from the communication port.

9. The circuit of claim 1, further including a MEMS connector circuit configured and arranged to
in response to the disconnection of an external connector from the communication port, monitor the communication port to detect the connection of an external connector thereto,
in response to detecting the connection of an external connector to the communication port, electrically couple the sensing control circuit to the communication port to detect a connection type at the communication port, and
after the connection type has been detected, electrically decouple the sensing control circuit from the communication port.

10. The circuit of claim 1, wherein the communication port is connected to a multipurpose antenna configured to receive different types of signals including signals providing at least one of data and power, and wherein the sensing control circuit is configured to detect a type of signal received via the multipurpose antenna and to control the plurality of MEMS switch circuits to electrically couple the multipurpose antenna to different internal circuits based upon the detected type of signal received via the multipurpose antenna.

11. The circuit of claim 1, wherein the sensing control circuit is configured to maintain the MEMS switch circuits in an open position until an input has been detected from an external connector connected to the communication port, to mitigate the coupling of an electrostatic discharge during connection of the external connector to the communication port.

12. The circuit of claim 1, wherein
the MEMS switch circuits are configured to block ESD pulses in an open state, and
the sensing control circuit is configured to maintain the MEMS switch circuits in an open position until an input has been received from an external connector connected to the communication port, to mitigate the coupling of an electrostatic discharge during connection of the external connector to the communication port.

13. The circuit of claim 1, wherein the sensing control circuit is configured to control the at least one of the MEMS switch circuits to open the MEMS switch circuit and disconnect one of said different circuits in the electric device therefrom in response to an operational characteristic of the one of said different circuits.

14. The circuit of claim 1, further including a shared electrical conductor between the communication port and the plurality of MEMS switch circuits, the plurality of MEMS switch circuits being configured to respectively couple the communication port to different circuits in the electronic device using the shared electrical conductor to provide connections between the communication port and MEMS switch circuits for electrically coupling both power and data between the communication port and the MEMS switch circuit.

15. A method for switching a connection between an communication port and a plurality of different circuits in an electronic device, the plurality of different circuits including power and data circuits, the method comprising:
sensing a type of connection at the communication port and, based upon the sensed type of connection, actuating at least one of a plurality of MEMS switch circuits between an open position in which the communication port is not electrically coupled via the at least one of the MEMS switch circuits, and a closed position in which the communication port is electrically coupled via the at least one of the MEMS switch circuits to at least one of the power and data circuits.

16. The method of claim 15, wherein actuating at least one of a plurality of MEMS switch circuits includes
in response to sensing a power connection at the communication port, actuating a first one of the MEMS switch circuits to couple power between the communication port and a power circuit in the electronic device, and
in response to sensing a data connection at the communication port, actuating a second one of the MEMS switch circuits to couple data between the communication port and a data circuit in the electronic device.

17. The method of claim 15, wherein
sensing a type of connection at the communication port includes sensing a frequency of a connection at the communication port,
actuating at least one of a plurality of MEMS switch circuits includes actuating at least one of the MEMS switch circuits to couple power between the communication port and a power circuit in the electronic device in response to sensing a low frequency (LF) connection at the communication port, and
actuating at least one of a plurality of MEMS switch circuits includes actuating at least one of the MEMS switch circuits to couple data between the communication port and a data circuit in the electronic device, in response to sensing connection of a higher frequency than the LF connection at the communication port.

18. The method of claim 15, wherein actuating at least one of a plurality of MEMS switch circuits includes applying a voltage to biasing circuits of at least one of the MEMS switch circuits and thereby cause a membrane of the one of the MEMS switch circuits to move between an open position in which a contact electrode in the membrane is electrically isolated from another contact electrode, and the closed position in which the contact electrodes are electrically coupled for coupling the communication port with at least one of the power and data circuits in the device.

19. The method of claim 15, further including
electrically coupling a sensing control circuit to the communication port for sensing the type of connection at the communication port, and
after the connection type has been detected, electrically decoupling the sensing control circuit from the communication port.

20. The method of claim 15,
further including, prior to actuating at least one of the plurality of MEMS switch circuits, maintaining the MEMS switch circuits in an open position to mitigate the coupling of an electrostatic discharge to the at least one of the power and data circuits during connection of an external connector to the communication port, and
wherein actuating at least one of a plurality of MEMS switch circuits includes, in response to detecting an input signal from an external connector connected to the communication port, actuating the at least one of the plurality of MEMS switches to electrically couple the external connector to at least one of the power and data circuits.

21. A switching circuit for an electronic device, the switching circuit comprising:
a communication port; and
a dynamic switch circuit including a plurality of switches respectively configured to selectively electrically couple the communication port to different circuits in the electronic device responsive to a type of connection detected at the communication port, in which
each of the switches is configured to operate at an on resistance Rₒₙ and off capacitance C_{off} having a product Rₒₙ* C_{off}<300 fs,
at least one of the switches is configured to couple power between the communication port and an internal circuit in the electronic device, and
at least one of the switches is configured to couple data between the communication port and an internal circuit in the electronic device.

22. The switching circuit of claim 21, further including a sensing control circuit configured to sense a type of connection at the communication port and, based upon the sensed type of connection, switch at least one of the switches between an open state in which the communication port is not electrically coupled via the at least one of the switches, and a closed state in which the communication port is electrically coupled via the at least one of the switches to at least one of the internal circuits.
